(19) United States
(12) Patent Application Publication
(10) Pub. No.: US 2022/0200565 A1
(43) Pub. Date: Jun. 23, 2022

(54) BULK-ACOUSTIC WAVE RESONATOR PACKAGE

(71) Applicant: SAMSUNG ELECTRO-MECHANICS CO., LTD., Suwon-si (KR)

(72) Inventors: Tae Kyung LEE, Suwon-si (KR); Seung Wook PARK, Suwon-si (KR); Seong Hun NA, Suwon-si (KR); Jae Hyun JUNG, Suwon-si (KR); Yeong Gyu LEE, Suwon-si (KR); Moon Chul LEE, Suwon-si (KR); Jin Suk SON, Suwon-si (KR); Jae Goon AUM, Suwon-si (KR)

(73) Assignee: SAMSUNG ELECTRO-MECHANICS CO., LTD., Suwon-si (KR)

(21) Appl. No.: 17/475,716

(22) Filed: Sep. 15, 2021

(30) Foreign Application Priority Data
Dec. 17, 2020 (KR) 10-2020-0177601

(51) Int. Cl. H03H 9/10; H03H 9/05; H03H 9/17

(52) U.S. Cl. CPC H03H 9/105; H03H 9/175; H03H 9/173; H03H 9/0533

(57) ABSTRACT

A bulk-acoustic wave resonator package includes a package substrate; a cover bonded to the package substrate; an acoustic wave resonator accommodated in an accommodation space defined by the package substrate and the cover; a conductive wire disposed in the accommodation space to electrically connect the acoustic wave resonator to the package substrate; and a bonding portion to fixedly couple the acoustic wave resonator to the package substrate. The bonding portion includes an adhesive member including silicon.

### CROSS-REFERENCE TO RELATED APPLICATION(S)

This application claims the benefit under 35 USC 119(a) of Korean Patent Application No. 10-2020-0177601 filed on Dec. 17, 2020 in the Korean Intellectual Property Office, the entire disclosure of which is incorporated herein by reference for all purposes.

### BACKGROUND

### 1. Field

The following description relates to a bulk-acoustic wave resonator package.

### 2. Description of Related Art

In accordance with the trend for the miniaturization of wireless communication devices, the miniaturization of high frequency component technology has been actively demanded. For example, a bulk-acoustic wave (BAW) resonator-type filter using semiconductor thin film wafer manufacturing technology may be used.

A bulk-acoustic wave resonator (BAW) is formed when a thin film type element, causing resonance by depositing a piezoelectric dielectric material on a silicon wafer, a semiconductor substrate, and using the piezoelectric characteristics thereof, is implemented as a filter.

Technological interest in 5G communications has been increasing, and the development of technologies that can be implemented in candidate bands is being undertaken.

However, in the case of 5G communication using a Sub 6 GHz (4 to 6 GHz) frequency band, since a bandwidth increases and a communication distance decreases, signal strength or power of the acoustic wave resonator may be increased.

Accordingly, there is demand for an acoustic wave resonator for ensuring long-term operational reliability with small fluctuations in the resonant frequency, even at high power.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a bulk-acoustic wave resonator package includes: a package substrate; a cover bonded to the package substrate; an acoustic wave resonator accommodated in an accommodation space defined by the package substrate and the cover; a conductive wire disposed in the accommodation space to electrically connect the acoustic wave resonator to the package substrate; and a bonding portion configured to fixedly couple the acoustic wave resonator to the package substrate, wherein the bonding portion includes an adhesive member including silicon.

The acoustic wave resonator may include: a support substrate; a resonator including a first electrode, a piezoelectric layer, and a second electrode sequentially stacked on the support substrate; and a hydrophobic layer disposed along a surface of the resonator.

A cavity may be defined between the resonator and the support substrate, and the hydrophobic layer may be disposed on an inner wall of the cavity.

The hydrophobic layer may include a self-assembled monolayer (SAM) forming material.

The hydrophobic layer may include a fluorine (F) component.

The hydrophobic layer may include fluorocarbon having a silicon head.

The package substrate may include a ceramic substrate.

The conductive wire may include any one material of copper, gold, platinum, and aluminum.

The bulk-acoustic wave resonator package may include: an insertion layer partially disposed in the resonator, and disposed between the first electrode and the piezoelectric layer, and the piezoelectric layer may be at least partially raised by the insertion layer.

The insertion layer may include an inclined surface, and the piezoelectric layer may include a piezoelectric portion disposed on the first electrode, and an inclined portion disposed on the inclined surface of the insertion layer.

In a cross-section cut the resonator, an end of the second electrode may be disposed on the inclined portion of the piezoelectric layer, or may be disposed along a boundary between the piezoelectric portion and the inclined portion.

The piezoelectric layer may include an extension portion disposed on an external side of the inclined portion, and at least a portion of the second electrode may be disposed on the extension portion of the piezoelectric layer.

The bulk-acoustic wave resonator package may include a Bragg reflective layer disposed below the resonator, and the Bragg reflective layer may include a first reflective layer having a first acoustic impedance and a second reflective layer stacked on the first reflective layer and having a second acoustic impedance, which is lower than the first acoustic impedance.

A groove-shaped cavity may be disposed on an upper surface of the support substrate, and the resonator may be spaced apart from the support substrate by the cavity.

The bulk-acoustic wave resonator package may include a connection substrate disposed between the support substrate and the package substrate and mounted on the package substrate, and the bonding portion may be interposed between the support substrate and the connection substrate.

In another general aspect, a bulk-acoustic wave resonator package includes: a package substrate; a support substrate bonded to the package substrate; a resonator disposed on the support substrate, and including a sequentially stacked first electrode, piezoelectric layer, and second electrode; a bonding wire electrically connecting the resonator to the package substrate; and a cover configured to accommodate the resonator, the support substrate, and the bonding wire therein and bonded to the package substrate, wherein a hydrophobic layer is disposed on a surface of the resonator.

Other features and aspects will be apparent from the following detailed description, the drawings, and the claims.

### BRIEF DESCRIPTION OF DRAWINGS

FIG. 1 is a plan view of a bulk-acoustic wave resonator according to an example.

FIG. 2 is a cross-sectional view taken along line I-I′ of FIG. 1.

FIG. 3 is a cross-sectional view taken along line II-II′ of FIG. 1.

FIG. 4 is a cross-sectional view taken along line III-III′ in FIG. 1.

FIG. 5 is a cross-sectional view schematically illustrating a bulk-acoustic wave resonator package according to an example.

FIG. 6 is a view illustrating a value of measuring a resonant frequency of the acoustic wave resonator package.

FIG. 7 is a view schematically illustrating a bulk-acoustic wave resonator according to another example.

FIG. 8 is a view schematically illustrating a bulk-acoustic wave resonator according to another example.

FIG. 9 is a view schematically illustrating a bulk-acoustic wave resonator according to another example.

FIG. 10 is a view schematically illustrating a bulk-acoustic wave resonator according to another example.

FIG. 11 is a view schematically illustrating a bulk-acoustic wave resonator package according to another example.

FIG. 12 is a view schematically illustrating a bulk-acoustic wave resonator package according to another example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The drawings may not be to scale, and the relative size, proportions, and depiction of elements in the drawings may be exaggerated for clarity, illustration, and convenience.

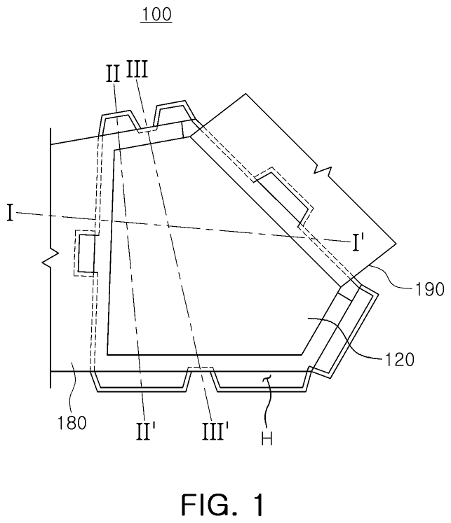

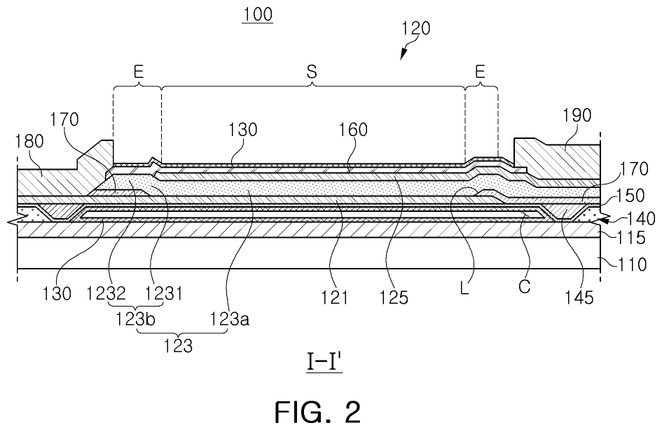

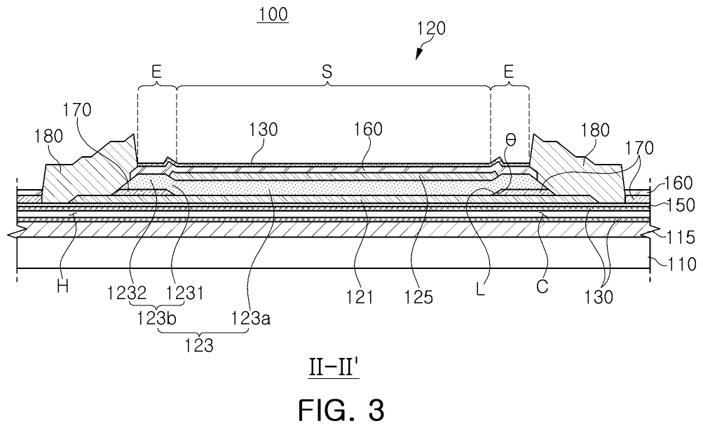

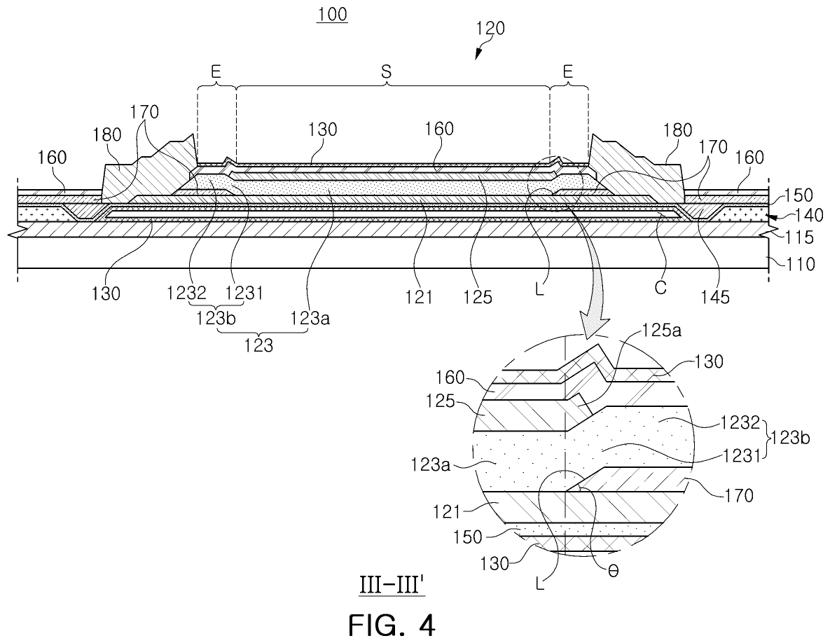

FIG. 1 is a plan view of an acoustic wave resonator according to an example, FIG. 2 is a cross-sectional view taken along I-I′ of FIG. 1, FIG. 3 is a cross-sectional view taken along II-II′ of FIG. 1, and FIG. 4 is a cross-sectional view taken along III-III′.

Referring to FIGS. 1 to 4, an acoustic wave resonator 100 may be a bulk-acoustic wave (BAW) resonator, and may include a support substrate 110, an insulating layer 115, a resonator 120, and hydrophobic layer 130.

The support substrate 110 may be a silicon substrate. For example, a silicon wafer may be used as the support substrate 110, or a silicon on insulator (SOI)-type substrate may be used.

The insulating layer 115 may be provided on an upper surface of the support substrate 110 to electrically isolate the support substrate 110 and the resonator 120. The insulating layer 115 prevents the support substrate 110 from being etched by an etching gas when a cavity C is formed in a manufacturing process of the acoustic wave resonator.

In this case, the insulating layer 115 may be formed of at least one of silicon dioxide (SiO₂), silicon nitride (Si₃N₄), aluminum oxide (Al₂O₃), and aluminum nitride (AlN), and may be formed through any one process of chemical vapor deposition, RF magnetron sputtering, and evaporation.

A support layer 140 may be formed on the insulating layer 115, and may be disposed around the cavity C and an etch stop portion 145 to surround the cavity C and the etch stop portion 145 inside the support layer 140.

The cavity C may be formed as an empty space, and may be formed by removing a portion of a sacrificial layer, and the support layer 140 may be formed as a remaining portion of the sacrificial layer.

The support layer 140 may be formed of a material such as polysilicon or a polymer, which may be relatively easy to etch. However, the support layer 140 is not limited to such materials.

The etch stop portion 145 is disposed along a boundary of the cavity C. The etch stop portion 145 may be provided to prevent etching from being performed beyond a cavity region in a process of forming the cavity C.

A membrane layer 150 may be formed on the support layer 140, and form an upper surface of the cavity C. Therefore, the membrane layer 150 may also be formed of a material that is not easily removed in the process of forming the cavity C.

For example, when a halide-based etching gas such as fluorine (F), chlorine (CI), or the like is used to remove a portion (e.g., a cavity region) of the support layer 140, the membrane layer 150 may be formed of a material having low reactivity with the etching gas. For example, the membrane layer 150 may include at least one of silicon dioxide (SiO₂) and silicon nitride (Si₃N₄).

The membrane layer 150 may be formed of a dielectric layer containing at least one material of magnesium oxide (MgO), zirconium oxide (ZrO₂), aluminum nitride (AlN), lead zirconate titanate (PZT), gallium arsenide (GaAs), hafnium oxide (HfO₂), and aluminum oxide (Al₂O₃), titanium oxide (TiO₂), and zinc oxide (ZnO), or a metal layer containing at least one material of aluminum (Al), nickel (Ni), chromium (Cr), platinum (Pt), gallium (Ga), and hafnium (Hf). However, a configuration of the membrane layer 150 is not limited thereto.

The resonator 120 includes a first electrode 121, a piezoelectric layer 123, and a second electrode 125. The resonator 120 is configured such that the first electrode 121, the piezoelectric layer 123, and the second electrode 125 are stacked in order from a bottom layer. Therefore, the piezoelectric layer 123 in the resonator 120 is disposed between the first electrode 121 and the second electrode 125.

Since the resonator 120 is formed on the membrane layer 150, the membrane layer 150, the first electrode 121, the piezoelectric layer 123, and the second electrode 125 are sequentially stacked on the support substrate 110, to form the resonator 120.

The resonator 120 may resonate the piezoelectric layer 123 according to signals applied to the first electrode 121 and the second electrode 125 to generate a resonant frequency and an anti-resonant frequency.

The resonator 120 may be divided into a central portion S in which the first electrode 121, the piezoelectric layer 123, and the second electrode 125 are stacked to be substantially flat, and an extension portion E in which an insertion layer 170 is interposed between the first electrode 121 and the piezoelectric layer 123.

The central portion S is a region disposed in a center of the resonator 120, and the extension portion E is a region disposed along a periphery of the central portion S. Therefore, the extension portion E is a region extended from the central portion S externally, and may be a region formed to have a continuous annular shape along the periphery of the central portion S. However, if necessary, the extension portion E may be configured to have a discontinuous annular shape, in which some regions are disconnected.

Accordingly, as shown in FIG. 2, in the cross-section of the resonator 120 cut so as to cross the central portion S, the extension portion E is disposed on both ends of the central portion S, respectively. The insertion layer 170 is disposed on both sides of the extension portion E disposed on both ends of the central portion S.

The insertion layer 170 has an inclined surface L of which a thickness becomes greater as a distance from the central portion S increases.

In the extension portion E, the piezoelectric layer 123 and the second electrode 125 are disposed on the insertion layer 170. Therefore, the piezoelectric layer 123 and the second electrode 125 located in the extension portion E have an inclined surface along the shape of the insertion layer 170.

The extension portion E is included in the resonator 120, and accordingly, resonance may also occur in the extension portion E. However, the configuration is not limited thereto, and resonance may not occur in the extension portion E depending on the structure of the extension portion E, but resonance may occur only in the central portion S.

The first electrode 121 and the second electrode 125 may be formed of a conductor, for example, may be formed of gold, molybdenum, ruthenium, iridium, aluminum, platinum, titanium, tungsten, palladium, tantalum, chromium, nickel, or a metal containing at least one thereof, but are not limited to such a configuration.

In the resonator 120, the first electrode 121 is formed to have a larger area than the second electrode 125, and a first metal layer 180 is disposed along an outer periphery of the first electrode 121 on the first electrode 121. Therefore, the first metal layer 180 may be disposed to be spaced apart from the second electrode 125 by a predetermined distance, and may be disposed in a form surrounding the resonator 120.

Since the first electrode 121 is disposed on the membrane layer 150, the first electrode 121 is formed to be entirely flat. On the other hand, since the second electrode 125 is disposed on the piezoelectric layer 123, curving may be formed in the second electrode 125 corresponding to the shape of the piezoelectric layer 123.

The first electrode 121 may be used as any one of an input electrode and an output electrode for inputting and outputting an electrical signal such as a radio frequency (RF) signal, or the like.

The second electrode 125 is entirely disposed in the central portion S, and partially disposed in the extension portion E. Accordingly, the second electrode 125 may be divided into a portion disposed on a piezoelectric portion 123a of the piezoelectric layer 123, and a portion disposed on a curved portion 123b of the piezoelectric layer 123.

More specifically, in the present example, the second electrode 125 is disposed to cover an entirety of the piezoelectric portion 123a and a portion of an inclined portion 1231 of the piezoelectric layer 123. Accordingly, a portion of the second electrode 125 (portion 125a shown in FIG. 4) disposed in the extension portion E is formed to have a smaller area than an inclined surface of the inclined portion 1231, and the second electrode 125 in the resonator 120 is formed to have a smaller area than the piezoelectric layer 123.

Accordingly, as shown in FIG. 2, in a cross-section of the resonator 120 cut so as to cross the central portion S, an end of the second electrode 125 may be disposed in the extension portion E. The end of the second electrode 125 disposed in the extension portion E may be disposed such that at least a portion thereof overlaps the insertion layer 170. For example, ‘overlap’ means that if the second electrode 125 was to be projected onto a plane on which the insertion layer 170 is disposed, a shape of the second electrode 125 projected on the plane would overlap the insertion layer 170.

The second electrode 125 may be used as any one of an input electrode and an output electrode for inputting and outputting an electrical signal such as a radio frequency (RF) signal, or the like. That is, when the first electrode 121 is used as the input electrode, the second electrode 125 may be used as the output electrode, and when the first electrode 121 is used as the output electrode, the second electrode 125 may be used as the input electrode.

As illustrated in FIG. 4, when the end of the second electrode 125 is positioned on the inclined portion 1231 of the piezoelectric layer 123, since a local structure of an acoustic impedance of the resonator 120 is formed in a sparse/dense/sparse/dense structure from the central portion S, a reflective interface reflecting a lateral wave inwardly of the resonator 120 increases. Therefore, since most lateral waves could not flow outwardly of the resonator 120, and are reflected and then flow to an interior of the resonator 120, the performance of the acoustic wave resonator may be improved.

The piezoelectric layer 123 is a portion converting electrical energy into mechanical energy in a form of elastic waves through a piezoelectric effect, and is formed on the first electrode 121 and the insertion layer 170.

As a material of the piezoelectric layer 123, zinc oxide (ZnO), aluminum nitride (AlN), doped aluminum nitride, lead zirconate titanate, quartz, and the like can be selectively used. In the case of doped aluminum nitride, a rare earth metal, a transition metal, or an alkaline earth metal may be further included. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). In addition, the alkaline earth metal may include magnesium (Mg).

In order to improve piezoelectric properties, when a content of elements doped with aluminum nitride (AlN) is less than 0.1 at %, a piezoelectric property higher than that of aluminum nitride (AlN) cannot be realized. When the content of the elements exceeds 30 at %, it is difficult to fabricate and control the composition for deposition, such that uneven crystalline phases may be formed.

Therefore, in the present example, the content of elements doped with aluminum nitride (AlN) may be in a range of 0.1 to 30 at %.

In the present example, the piezoelectric layer is doped with scandium (Sc) in aluminum nitride (AlN). In this case, a piezoelectric constant may be increased to increase Kt² of the acoustic wave resonator.

The piezoelectric layer 123 includes the piezoelectric portion 123a disposed in the central portion S and the curved portion 123b disposed in the extension portion E.

The piezoelectric portion 123a is a portion directly stacked on the upper surface of the first electrode 121. Therefore, the piezoelectric portion 123a is interposed between the first electrode 121 and the second electrode 125 and is formed as a flat shape, together with the first electrode 121 and the second electrode 125.

The curved portion 123b may be defined as a region extending from the piezoelectric portion 123a externally and positioned in the extension portion E.

The curved portion 123b is disposed on the insertion layer 170, and is formed in a shape in which the upper surface thereof is raised along the shape of the insertion layer 170. Accordingly, the piezoelectric layer 123 is curved at a boundary between the piezoelectric portion 123a and the curved portion 123b, and the curved portion 123b is raised corresponding to the thickness and shape of the insertion layer 170.

The curved portion 123b may be divided into the inclined portion 1231 and an extension portion 1232.

The inclined portion 1231 is a portion formed to be inclined along the inclined surface L of the insertion layer 170. The extension portion 1232 is a portion extending from the inclined portion 1231 externally.

The inclined portion 1231 may be formed to be parallel to the inclined surface L of the insertion layer 170, and an inclination angle of the inclined portion 1231 may be formed to be the same as an inclination angle of the inclined surface L of the insertion layer 170.

The insertion layer 170 is disposed along a surface formed by the membrane layer 150, the first electrode 121, and the etch stop portion 145. Therefore, the insertion layer 170 is partially disposed in the resonator 120, and is disposed between the first electrode 121 and the piezoelectric layer 123.

The insertion layer 170 is disposed at a periphery of the central portion S to support the curved portion 123b of the piezoelectric layer 123. Accordingly, the curved portion 123b of the piezoelectric layer 123 may be divided into the inclined portion 1231 and the extension portion 1232 according to the shape of the insertion layer 170.

In the present example, the insertion layer 170 is disposed in a region except for the central portion S. For example, the insertion layer 170 may be disposed on the support substrate 110 in an entire region except for the central portion S, or in some regions.

The insertion layer 170 is formed to have a thickness becoming greater as a distance from the central portion S increases. Thereby, the insertion layer 170 is formed of the inclined surface L having a constant inclination angle Θ of the side surface disposed adjacent to the central portion S.

When the inclination angle Θ of the side surface of the insertion layer 170 is formed to be smaller than 5°, in order to manufacture the same, since the thickness of the insertion layer 170 should be formed to be very thin or an area of the inclined surface L should be formed to be excessively large, it is practically difficult to be implemented.

In addition, when the inclination angle Θ of the side surface of the insertion layer 170 is formed to be greater than 70°, the inclination angle of the piezoelectric layer 123 or the second electrode 125 stacked on the insertion layer 170 is also formed to be greater than 70°. In this case, since the piezoelectric layer 123 or the second electrode 125 stacked on the inclined surface L is excessively curved, cracks may be generated in the curved portion.

Therefore, in the present example, the inclination angle Θ of the inclined surface L is formed in a range of 5° or more and 70° or less.

The inclined portion 1231 of the piezoelectric layer 123 is formed along the inclined surface L of the insertion layer 170, and thus is formed at the same inclination angle as the inclined surface L of the insertion layer 170. Therefore, the inclination angle of the inclined portion 1231 is also formed in a range of 5° or more and 70° or less, similarly to the inclined surface L of the insertion layer 170. The configuration may also be equally applied to the second electrode 125 stacked on the inclined surface L of the insertion layer 170.

The insertion layer 170 may be formed of a dielectric material such as silicon oxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), gallium arsenide (GaAs), hafnium oxide (HfO₂), titanium oxide (TiO₂), zinc oxide (ZnO), or the like, but may be formed of a material, different from that of the piezoelectric layer 123.

The insertion layer 170 may be implemented with a metal material. When the acoustic wave resonator of the present example is used for 5G communications, heat generated from the resonator 120 needs to be smoothly discharged because a lot of heat is generated from the resonator 120. To this end, the insertion layer 170 of the present example may be made of an aluminum alloy material containing scandium (Sc).

The resonator 120 may be disposed to be spaced apart from the support substrate 110 through the cavity C formed as a void.

The cavity C may be formed by removing a portion of the support layer 140 by supplying an etching gas (or an etching solution) to an inlet hole (H in FIGS. 1 and 3) during a manufacturing process of the acoustic wave resonator 100.

Accordingly, the cavity C is composed of a space in which an upper surface (a ceiling surface) and a side surface (a wall surface) are formed by the membrane layer 150, and a bottom surface thereof is formed by the support substrate 110 or the insulating layer 115. The membrane layer 150 may be formed only on the upper surface (the ceiling surface) of the cavity C according to the order of the manufacturing method.

A protective layer 160 is disposed along the surface of the acoustic wave resonator 100 to protect the acoustic wave resonator 100 from the outside. The protective layer 160 may be disposed along a surface formed by the second electrode 125 and the curved portion 123b of the piezoelectric layer 123.

The protective layer 160 may be partially removed for frequency control in a final process during the manufacturing process. For example, the thickness of the protective layer 160 may be controlled through frequency trimming during the manufacturing process.

To this end, the protective layer 160 may include one of silicon oxide (SiO₂), silicon nitride (Si₃N₄), magnesium oxide (MgO), zirconium oxide (ZrO₂), aluminum nitride (AlN), lead zirconate titanate (PZT), gallium Arsenic (GaAs), hafnium oxide (HfO₂), aluminum oxide (Al₂O₃), titanium oxide (TiO₂), zinc oxide (ZnO), amorphous silicon (a-Si), and polycrystalline silicon (p-Si), suitable for frequency trimming, but is not limited to such materials.

The first electrode 121 and the second electrode 125 may extend externally of the resonator 120. The first metal layer 180 and a second metal layer 190 may be disposed on an upper surface of the extension portion E, respectively.

The first metal layer 180 and the second metal layer 190 may be made of any one material of gold (Au), a gold-tin (Au—Sn) alloy, copper (Cu), a copper-tin (Cu—Sn) alloy, and aluminum (Al), and an aluminum alloy. Here, the aluminum alloy may be an aluminum-germanium (Al—Ge) alloy or an aluminum-scandium (Al—Sc) alloy.

The first metal layer 180 and the second metal layer 190 may serve to a connection wiring electrically connecting the electrodes 121 and 125 of the acoustic wave resonator 100 on the substrate 110 and electrodes of other acoustic wave resonators disposed adjacent to each other.

At least a portion of the first metal layer 180 may be in contact with the protective layer 160 and may be bonded to the first electrode 121.

In the resonator 120, the first electrode 121 may be formed to have a larger area than the second electrode 125, and the first metal layer 180 may be formed on a peripheral portion of the first electrode 121.

Therefore, the first metal layer 180 may be disposed at the periphery of the resonator 120, and accordingly, may be disposed to surround the second electrode 125. However, the configuration is not limited thereto.

In the acoustic wave resonator 100, the hydrophobic layer 130 may be disposed on a surface of the protective layer 160 and an inner wall of the cavity C.

When an acoustic wave resonator is used in a humid environment or is left at room temperature for a long period of time, a hydroxyl group (OH group) is adsorbed to the protective layer 160 of the acoustic wave resonator such that a problem in which frequency fluctuations increase due to mass loading or resonance performance deterioration, may occur.

For example, when a hydrophobic layer 130 is not formed on a surface of the bulk-acoustic wave resonator, a hydroxyl group (an OH group) may be more easily adsorbed to the protective layer 160, to form hydroxylate. Since hydroxylate has a high surface energy and is unstable, it attempts to lower the surface energy by adsorbing water, and the like, resulting in mass loading.

On the other hand, when the hydrophobic layer 130 is provided on a surface of the acoustic wave resonator, since the surface energy is low and stable, there is no need to lower the surface energy by adsorbing water, a hydroxyl group (OH group), and the like. Therefore, the hydrophobic layer 130 may serve to suppress adsorption of water, hydroxyl group (OH group), and the like, thereby significantly reducing frequency fluctuations, and thus maintaining uniform resonator performance.

The hydrophobic layer 130 may be formed of a self-assembled monolayer (SAM) formation material, rather than a polymer. When the hydrophobic layer 130 is formed of a polymer, mass due to the polymer may affect the resonator 120. However, in the acoustic wave resonator according to an example, since the hydrophobic layer 130 is formed of a self-assembled monolayer, it is possible to significantly reduce frequency fluctuations of the acoustic wave resonator. In addition, the thickness of the hydrophobic layer 130 according to the position in the cavity C may be uniformly formed.

The hydrophobic layer 130 may be formed by performing vapor deposition on a precursor for having hydrophobicity. In this case, the hydrophobic layer 130 may be deposited as a monolayer having a thickness of 100 Å or less (e.g., several Å to tens of Å). As the precursor material for having hydrophobicity, it may be formed of a material having a contact angle of 90° or more with water after deposition. For example, the hydrophobic layer 130 may contain a fluorine (F) component, and may include fluorine (F) and silicon (Si). Specifically, fluorocarbon having a silicon head may be used, but the configuration is not limited thereto.

In order to improve adhesion between the self-assembled monolayer constituting the hydrophobic layer 130 and the protective layer 160, a bonding layer (not shown) may first be formed on a surface of the protective layer 160 prior to forming the hydrophobic layer 130.

The bonding layer may be formed by performing vapor deposition on a precursor having a hydrophobic functional group on a surface of the protective layer 160.

As the precursor material used for deposition of the bonding layer, hydrocarbon having a silicon head, or siloxane having a silicon head may be used, but is not limited thereto.

Since the hydrophobic layer 130 is formed after the first metal layer 180 and the second metal layer 190 are formed, the hydrophobic layer 130 may be formed along surfaces of the protective layer 160, the first metal layer 180, and the second metal layer 190.

In the drawings, an example in which the hydrophobic layer 130 is not disposed on the surfaces of the first metal layer 180 and the second metal layer 190 is illustrated, but the configuration is not limited thereto. The hydrophobic layer 130 may also be disposed on the surfaces of the first metal layer 180 and the second metal layer 190, as needed.

The hydrophobic layer 130 may be disposed not only on an upper surface of the protective layer 160, but also on an inner surface of the cavity C.

The hydrophobic layer 130 formed in the cavity C may be formed over an entire inner wall forming the cavity C. Accordingly, the hydrophobic layer 130 may also be formed on a lower surface of the membrane layer 150 forming a lower surface of a resonator 120.

In this case, adsorption of hydroxyl groups to a lower portion of the resonator 120 can be suppressed.

The adsorption of hydroxyl groups may occur in the cavity C as well as in the protective layer 160. Therefore, in order to minimize the mass loading and the corresponding frequency drop due to the adsorption of hydroxyl groups, it is preferable to block adsorption of hydroxyl groups not only on the protective layer 160 but also on an upper surface of the cavity C (the lower surface of the membrane layer), which is the lower surface of the resonator.

In addition thereto, when the hydrophobic layer 130 is formed on the upper/lower surface or side surface of the cavity C, it may also provide an effect of suppressing an occurrence of a stiction phenomenon in which the resonator 120 sticks to the insulating layer 115 due to surface tension in a wet process or a cleaning process after the cavity C is formed.

Meanwhile, in the present embodiment, a case in which the hydrophobic layer 130 is formed over the entire inner wall of the cavity C is illustrated as an example, but is not limited thereto, and various modifications, such as a hydrophobic layer may be formed only on the upper surface of the cavity C, or a hydrophobic layer 130 may be formed on at least a portion of the lower surface and the side surface thereof, may be made.

Next, an acoustic wave resonator package according to an example will be described.

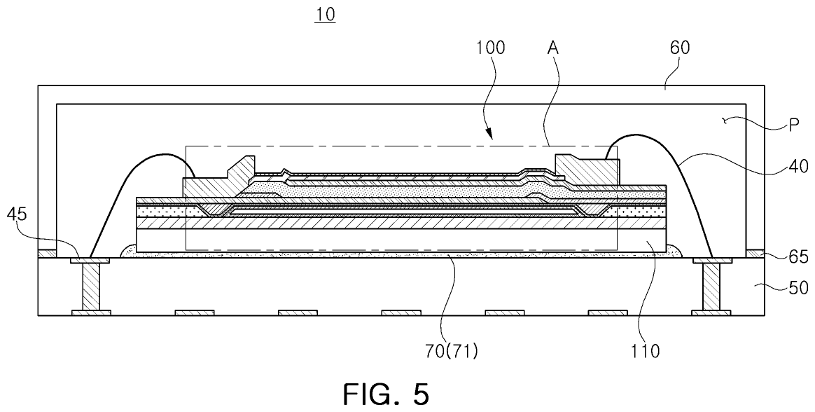

FIG. 5 is a cross-sectional view schematically illustrating an acoustic wave resonator package according to an example.

Referring to FIG. 5, an acoustic wave resonator package 10 includes at least one of acoustic wave resonators 100 described above. In addition, the acoustic wave resonator package 100 may include a package substrate 50 and a cover 60.

The acoustic wave resonator 100 may be bonded to the package substrate 50 via a bonding portion 70.

The acoustic wave resonator 100 may be bonded to the package substrate 50 through a silicon-based adhesive member 71. Accordingly, the bonding portion 70 may include a material including silicon.

The package substrate 50 may be formed of a ceramic substrate. However, the configuration is not limited thereto, and various types of support substrates well known in the art (e.g., printed circuit boards, flexible substrates, glass substrates, ceramic substrates, or the like) may be used.

The package substrate 50 may be a double-sided substrate in which a wiring layer is formed on both surfaces of one insulating layer. However, the configuration is not limited thereto, and a multilayer substrate formed by repeatedly stacking a plurality of insulating layers and a plurality of wiring layers may be used.

At least one electrode pad 45 may be formed on a surface of the package substrate 50. The electrode pad 45 may be electrically connected to the acoustic wave resonator 100 through a conductive wire 40.

In order to protect the resonator of the acoustic wave resonator 100 from an external environment, the cover 60 may be coupled to the package substrate 50.

The cover 60 may be formed in a form of a cap having an internal space in which the acoustic wave resonator 100 is accommodated. Accordingly, the cover 60 may include a sidewall and an upper surface portion connecting an upper portion of the sidewall, and may be bonded to the package substrate 50 in a form in which the sidewall thereof surrounds the acoustic wave resonator 100.

Accordingly, the acoustic wave resonator 100 may be accommodated in an accommodation space P formed by the cover 60 and the package substrate 50.

The cover 60 may be formed of a metal material, and may be bonded to the package substrate 50 through metal bonding. For example, a bonding member 65 for bonding the cover 60 and the package substrate 50 to each other may be interposed between the cover 60 and the package substrate 50, and a lower surface of the sidewall of the cover 60 may be used as a bonding surface with the package substrate 50.

As the acoustic wave resonator 100 is bonded to the package substrate 50, it is not easy to electrically connect the acoustic wave resonator 100 to the package substrate 50 through a lower surface of the acoustic wave resonator 100. Accordingly, the acoustic wave resonator 100 may be electrically connected to the package substrate 50 through the conductive wire 40. For example, one end of the conductive wire 40 may be bonded to the support substrate 110 of the acoustic wave resonator 100, and the other end of the conductive wire 40 may be bonded to the electrode pad 45 of the package substrate 50 to electrically connect the acoustic wave resonator 100 to the package substrate 50.

The conductive wire 40 may be made of any one of copper, gold, platinum, and aluminum. For example, as the conductive wire 40, a known bonding wire may be used, but is not limited thereto.

The acoustic wave resonator package 10 may be manufactured by bonding the acoustic wave resonator 100 to the package substrate 50 and then bonding the cover 60 to the package substrate 50.

However, in the process of bonding the acoustic wave resonator 100 to the package substrate 50, there is a problem in that particles such as mist and fumes generated by the adhesive member may be adsorbed onto the surface of the acoustic wave resonator 100. The particles change mass of the resonator of the acoustic wave resonator 100 and act as a factor to increase the fluctuation amount and standard deviation of the resonant frequency.

Therefore, if an amount of particles adhering to the surface of the resonator of the acoustic wave resonator 100 cannot be controlled below a certain level, a desired resonant frequency may not be obtained and may affect a yield of a product.

Accordingly, in order to suppress the particles generated by the adhesive member from being adsorbed onto the surface of the resonator of the acoustic wave resonator 100, the acoustic wave resonator 100 includes a hydrophobic layer, as described above. In addition, it is formed such that the bonding portion 70 includes the adhesive member 71 made of a silicone-based material.

When the fine particles (or an organic matter), described above are adsorbed to an interface of a certain material, chemical interaction (chemisorption) is performed in advance. Chemical interaction or chemical adsorption is characterized by strong interactions between atoms or molecules.

On the other hand, in physisorption, the interaction between atoms or molecules is weak compared to chemical adsorption, whereas in the case of polymers, the molecular chain is long, so an adsorption interface can be formed in a form of a multilayer structure.

When the acoustic wave resonator 100 is bonded to the package substrate 50 using an adhesive member 71, in order to minimize a change in mass of the resonator of the acoustic wave resonator 100 due to the organic particles described above, it is necessary to minimize the chemical adsorption between the organic matter and the acoustic wave resonator 100 first.

To this end, the acoustic wave resonator 100 is provided with the above-described hydrophobic layer on the surface thereof. When the hydrophobic layer is provided, since it is possible to suppress a hydroxyl group adsorption material from being generated by the adhesive member 71 from being adsorbed to the surface of the resonator of the acoustic wave resonator 100, chemical adsorption between the organic matter and the acoustic wave resonator 100 may be minimized.

In the acoustic wave resonator package 10, in order to minimize physical adsorption between the organic material and the acoustic wave resonator 100, an organic material composed of a single molecule, not a polymer, or an organic material with a short molecular chain is used as an adhesive member 71. Specifically, in the present example, the bonding portion 70 between the support substrate 110 of the acoustic wave resonator 100 and the package substrate 50 may be formed of a material having silicon. Accordingly, it is possible to suppress the organic material from being coupled to the surface of the resonator of the acoustic wave resonator 100 in a form of a multilayer structure during the physical adsorption process, thereby minimizing the mass load of the resonator of the acoustic wave resonator 100.

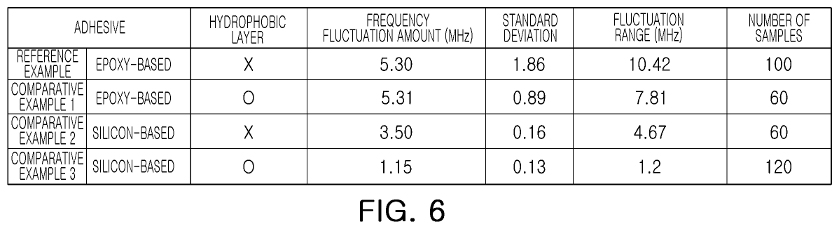

FIG. 6 is a view illustrating a value of measuring the resonant frequency of the acoustic wave resonator package. After a bonding portion 70 is formed with an epoxy-based adhesive member and a silicone-based adhesive member, a frequency fluctuation amount and standard deviation of the acoustic wave resonator package were measured, and results according to whether or not a hydrophobic layer is present were also measured and shown.

The frequency fluctuation refers to a difference in frequency between a resonant frequency before the acoustic wave resonator is packaged (before bonding the package substrate and the support substrate) and a resonant frequency after the acoustic wave resonator is packaged, and an average value thereof was shown. In addition, the standard deviation refers to dispersion of the frequency fluctuation amount, and a fluctuation range indicates a range of a maximum value and a minimum value for the frequency difference between the resonant frequency before the acoustic wave resonator is packaged and the resonant frequency after the packaging is completed.

In a Reference Example in FIG. 6, 100 samples were measured, and after bonding the acoustic wave resonator 100 without a hydrophobic layer to the package substrate 50 using an epoxy-based adhesive member, a resonant frequency was measured.

In the case of the Reference Example, it can be seen that a frequency fluctuation amount was measured as an average of 5.30 MHz, standard deviation was 1.86, and a fluctuation range was 10.42 MHz, which is very large.

In Comparative Example 1, 60 samples were measured, and after bonding the acoustic wave resonator 100 having the hydrophobic layer 130 to the package substrate 50 using an epoxy-based adhesive member, a resonant frequency was measured.

In the case of Comparative Example 1, it can be seen that a frequency fluctuation amount was measured as an average of 5.31 MHz, which is not significantly different from the reference example, but standard deviation was 0.86, and a fluctuation range was 7.81 MHz, which is slightly improved compared to the Reference example.

It can be seen as a result of minimizing chemical adsorption of particles through the hydrophobic layer 130. However, considering that the frequency fluctuation amount is still large and the fluctuation range is not significantly improved, in the process of curing the epoxy-based adhesive member, it can be understood that particles of a polymer component with a long molecular chain are physically adsorbed on the surface of the resonator 120.

In Comparative Example 2, 60 samples were measured, and after bonding the acoustic wave resonator 100 without the hydrophobic layer 130 to the package substrate 50 using a silicon-based adhesive member 71, a resonant frequency was measured.

It can be seen that the frequency fluctuation amount according to Comparative Example 2 was measured as an average of 3.5 MHz, and standard deviation was 0.16, which is slightly improved compared to the Reference example, and a fluctuation range was 4.67 MHz, which is also slightly improved compared to the Reference Example.

In the case of Comparative Example 2, overall characteristics of the acoustic wave resonator 100 were improved by suppressing physical adsorption of fine particles by using a silicon-based adhesive member. Therefore, it can be seen that the fluctuation of the resonant frequency is greatly improved only by suppressing the physical adsorption of the particles by using the silicon-based adhesive member 71. However, it can be seen that the fluctuation range is still large because the chemical adsorption cannot be suppressed.

In Comparative Example 3, 120 samples were measured, and after bonding the acoustic wave resonator 100 having the hydrophobic layer 130 to the package substrate 50 using a silicon-based adhesive member 71, a resonant frequency was measured.

It can be seen that a frequency fluctuation according to Comparative Example 3 was measured as an average of 1.15 MHz and standard deviation of 0.13, which were measured to be very low, and a variation range was also 1.2 MHz, which was significantly improved compared to the Reference Example or other Comparative examples.

In Comparative Example 3, physical adsorption of fine particles was suppressed by using the silicon-based adhesive member 71, and at the same time, chemical adsorption was suppressed through the hydrophobic layer 130, and in this case, it was confirmed that the fluctuation of the resonant frequency was significantly reduced.

Accordingly, in the acoustic wave resonator package according to the various examples, the support substrate 110 and the package substrate 50 may be bonded to each other via an adhesive member 71 including silicon, and a hydrophobic layer 130 may further be provided on a surface of the resonator 120.

In addition, a ceramic filler may be added to the adhesive member 71 including silicon to improve thermal conductivity of the bonding portion 70. As the ceramic filler, SiO₂, Al₂O₃, TiO₂, Si₃N₄, AlN, BN, or the like may be used, but is not limited thereto.

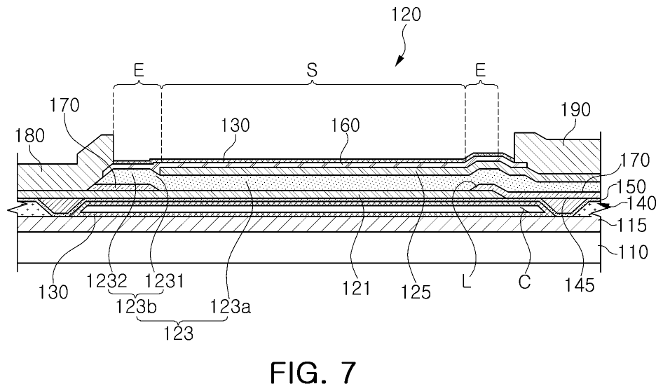

FIG. 7 is a cross-sectional view schematically illustrating an acoustic wave resonator according to another example.

Referring to FIG. 7, in the acoustic wave resonator according to the present example, in a cross-section of the resonator 120 cut to cross the central portion S, an end portion of the second electrode 125 is formed only on an upper surface of the piezoelectric portion 123a of the piezoelectric layer 123, and is not formed on the curved portion 123b. Accordingly, the end of the second electrode 125 is disposed along a boundary between the piezoelectric portion 123a and the inclined portion 1231.

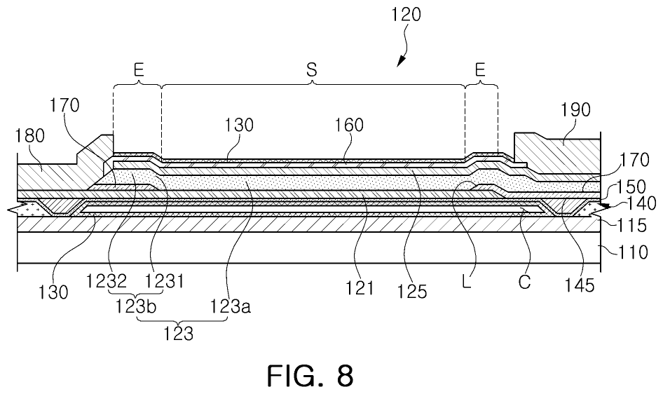

FIG. 8 is a cross-sectional view schematically illustrating an acoustic wave resonator according to another example.

In the acoustic wave resonator shown in the present example, a second electrode 125 is disposed on the entire upper surface of the piezoelectric layer 123 in the resonator 120, and accordingly, the second electrode 125 is formed not only on the inclined portion 1231 of the piezoelectric layer 123, but also on the extension portion 1232 thereof.

As such, the acoustic wave resonator according to the various examples may be modified into various shapes as needed.

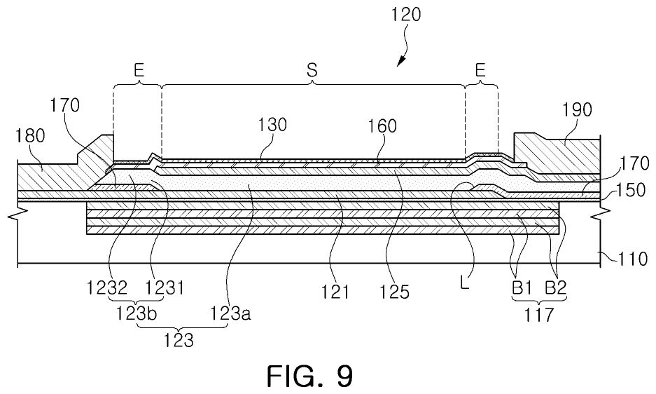

FIG. 9 is a cross-sectional view schematically illustrating an acoustic wave resonator according to another example.

Referring to FIG. 9, the acoustic wave resonator according to the present example is formed similarly to the acoustic wave resonator shown in FIG. 2, does not include a cavity (C in FIG. 2), and includes a Bragg reflector layer 117.

The Bragg reflective layer 117 may be disposed inside the support substrate 110, and may be formed by alternately staking a first reflective layer B1 having a high acoustic impedance and a second reflective layer B2 having a low acoustic impedance below the resonator 120.

In this case, the thickness of the first reflective layer B1 and the second reflective layer B2 may be defined to fit a specific wavelength, so that an acoustic wave may be reflected in a vertical direction toward the resonator 120, so that it can block that the acoustic wave is leaked to a lower side of the support substrate 110.

To this end, the first reflective layer B1 may be made of a material having a higher density than that of the second reflective layer B2. For example, any one of W, Mo, Ru, Ir, Ta, Pt, and Cu may be selectively used as the material of the first reflective layer B1. In addition, the second reflective layer B2 is made of a material having a lower density than that of the first reflective layer B1, and for example, any one of SiO₂, Si₃N₄, and AlN may be selectively used. However, the configuration is not limited thereto.

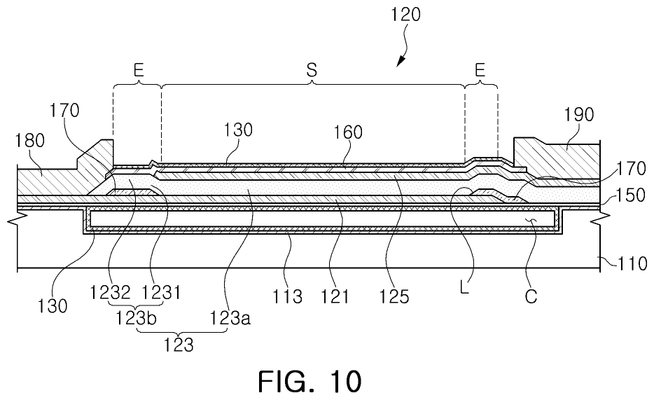

FIG. 10 is a cross-sectional view schematically illustrating an acoustic wave resonator according to another example.

Referring to FIG. 10, the acoustic wave resonator according to the present example is formed similarly to the acoustic wave resonator shown in FIG. 2, and in the acoustic wave resonator, a cavity C is not formed by partially removing the supporting substrate 110 without forming the cavity C on the supporting substrate 110.

The cavity C of the present example may be formed by partially etching an upper surface of the support substrate 110. Both dry etching and wet etching may be used for etching the support substrate 110. A barrier layer 113 may be formed on an inner surface of the cavity (C). The barrier layer 113 may protect the support substrate 110 from an etching solution used in the process of forming the resonator 120.

The barrier layer 113 may be formed of a dielectric layer such as AlN or SiO₂, or the like, but is not limited to such materials, and various materials may be used as long as it can protect the support substrate 110 from an etching solution.

In addition, a hydrophobic layer 130 may be formed on the barrier layer 113.

The acoustic wave resonator shown in FIGS. 7 to 10 is a portion disposed in part A of FIG. 5, and may be bonded to the package substrate 50 through a silicon-based adhesive member 71, respectively, and a hydrophobic layer 130 may be disposed on a surface of the resonator.

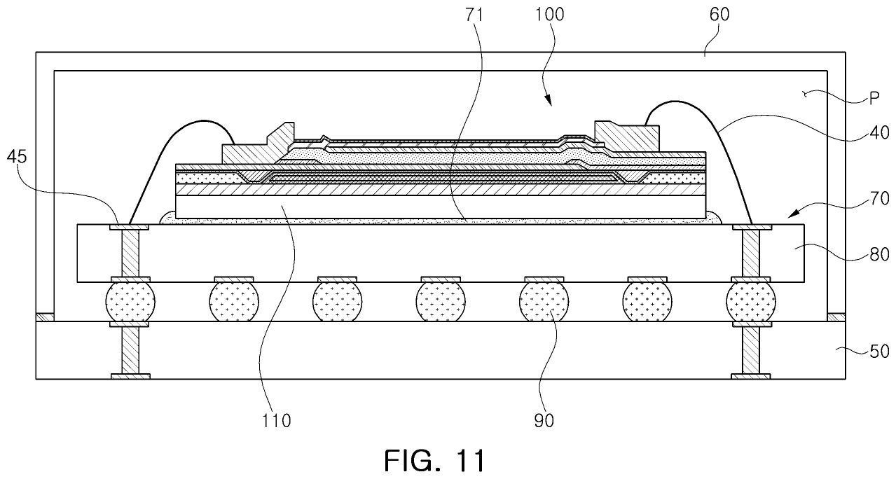

FIG. 11 is a cross-sectional view schematically illustrating an acoustic wave resonator package according to another example.

Referring to FIG. 11, the acoustic wave resonator package of the present example may include a bonding portion 70, fixing the acoustic wave resonator 100 to the package substrate 50, an adhesive member 71, a connection substrate 80, and a connection member 90.

The connection substrate 80 may be disposed between the support substrate 110 of the acoustic wave resonator 100 and the package substrate 50 and mounted on the package substrate 50.

In the present example, the connection substrate 80 may be a double-sided substrate in which a wiring layer is formed on both surfaces of one insulating layer. However, the configuration is not limited thereto, and a multilayer substrate formed by repeatedly stacking a plurality of insulating layers and a plurality of wiring layers may be used.

In addition, various types of support substrates well known in the art (e.g., printed circuit boards, flexible substrates, glass substrates, ceramic substrates, or the like) may be used as the connection substrate 80.

One or a plurality of acoustic wave resonators 100 may be disposed on the connection substrate 80. Accordingly, the plurality of acoustic wave resonators 100 may be electrically connected to each other through the connection substrate 80.

The acoustic wave resonator 100 may be bonded to the connection substrate 80 through an adhesive member 71, and may be electrically connected to the connection substrate 80 through a conductive wire 40. Accordingly, the package substrate 50 may be electrically connected to the acoustic wave resonator via the conductive wire 40 and the connection substrate 80. However, the configuration is not limited thereto, and if necessary, it may also be configured such that at least one conductive wire directly connects the acoustic wave resonator 100 and the package substrate 50.

As the adhesive member 71, a silicon-based material including silicon may be used as in the above-described examples, and thus, the same effect as in the above-described embodiments may be provided.

In the present example, the connection substrate 80 and the package substrate 50 may be electrically and physically connected through a conductive connection member 90 such as solder. For example, after a solder paste is disposed between the connection substrate 80 and the package substrate 50, the conductive connection member 90 may be formed through a reflow process. Accordingly, the connection substrate 80 may electrically connect the acoustic wave resonator 100 and the package substrate 50.

However, the configuration is not limited thereto, and it is also possible to bond the connection substrate 80 and the package substrate 50 to each other using a silicon-based material such as the adhesive member 71. In this case, the connection substrate 80 and the package substrate 50 may be electrically connected to each other through a conductive wire.

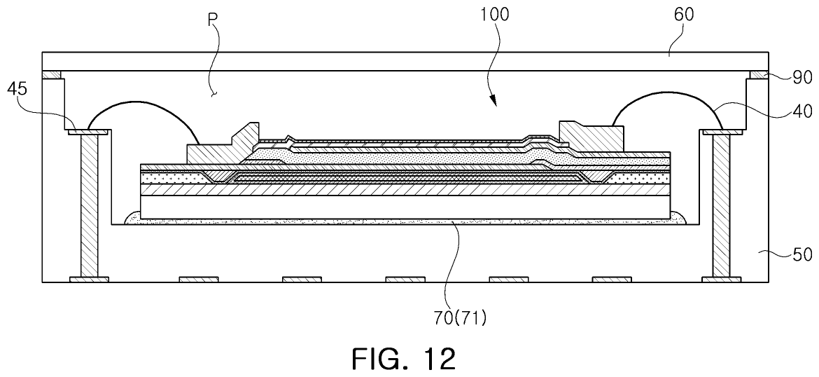

FIG. 12 is a cross-sectional view schematically illustrating an acoustic wave resonator package according to another example.

Referring to FIG. 12, in the acoustic wave resonator package of the present example, an accommodation space P may be provided in the package substrate 80. The acoustic wave resonator 100 may be accommodated in the accommodation space P and coupled to the package substrate 50.

The accommodation space P may be formed in a form of a groove, and may be formed as a space having a size for completely accommodating the acoustic wave resonator 100. Accordingly, the acoustic wave resonator 100 accommodated in the accommodation space P may not protrude to an external portion of the package substrate 50.

A step may be formed on a side surface of the accommodation space P, and an electrode pad 45 to which a conductive wire is bonded may be disposed on one surface of the step. However, the configuration is not limited thereto, and the electrode pads may be disposed at various positions as needed, such as forming an electrode pad on a bottom surface of the accommodation space P.

The cover 60 of the present example may be formed in a flat plate shape. Accordingly, the cover 60 may be seated on an upper end surface of the package substrate 50 and bonded to the package substrate 50. A connection member 90 for bonding the cover 60 and the package substrate 50 to each other may be interposed between the cover 60 and the package substrate 50, but the configuration is not limited thereto.

As set forth above, since the bulk-acoustic wave resonator package according to the various examples can minimize adsorption of particles generated during the manufacturing process, fluctuations in the resonant frequency can be minimized.

While this disclosure includes specific examples, it will be apparent after an understanding of the disclosure of this application that various changes in forms and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk-acoustic wave resonator package, comprising:
a package substrate;
a cover bonded to the package substrate;
an acoustic wave resonator accommodated in an accommodation space defined by the package substrate and the cover;
a conductive wire disposed in the accommodation space and configured to electrically connect the acoustic wave resonator to the package substrate; and
a bonding portion configured to fixedly couple the acoustic wave resonator to the package substrate,
wherein the bonding portion comprises an adhesive member including silicon.

2. The bulk-acoustic wave resonator package of claim 1, wherein the acoustic wave resonator comprises:
a support substrate;
a resonator comprising a first electrode, a piezoelectric layer, and a second electrode sequentially stacked on the support substrate; and
a hydrophobic layer disposed along a surface of the resonator.

3. The bulk-acoustic wave resonator package of claim 2, wherein a cavity is defined between the resonator and the support substrate,
wherein the hydrophobic layer is disposed on an inner wall of the cavity.

4. The bulk-acoustic wave resonator package of claim 2, wherein the hydrophobic layer comprises a self-assembled monolayer (SAM) forming material.

5. The bulk-acoustic wave resonator package of claim 2, wherein the hydrophobic layer comprises a fluorine (F) component.

6. The bulk-acoustic wave resonator package of claim 2, wherein the hydrophobic layer comprises fluorocarbon having a silicon head.

7. The bulk-acoustic wave resonator package of claim 2, wherein the package substrate is comprises a ceramic substrate.

8. The bulk-acoustic wave resonator package of claim 1, wherein the conductive wire comprises any one material of copper, gold, platinum, and aluminum.

9. The bulk-acoustic wave resonator package of claim 2, further comprising:
an insertion layer partially disposed in the resonator, and disposed between the first electrode and the piezoelectric layer,
wherein the piezoelectric layer is at least partially raised by the insertion layer.

10. The bulk-acoustic wave resonator package of claim 9, wherein the insertion layer comprises an inclined surface,
wherein the piezoelectric layer comprises a piezoelectric portion disposed on the first electrode, and an inclined portion disposed on the inclined surface of the insertion layer.

11. The bulk-acoustic wave resonator package of claim 10, wherein in a cross-section cut the resonator, an end of the second electrode is disposed on the inclined portion of the piezoelectric layer, or disposed along a boundary between the piezoelectric portion and the inclined portion.

12. The bulk-acoustic wave resonator package of claim 10, wherein the piezoelectric layer comprises an extension portion disposed on an external side of the inclined portion,
wherein at least a portion of the second electrode is disposed on the extension portion of the piezoelectric layer.

13. The bulk-acoustic wave resonator package of claim 2, further comprising a Bragg reflective layer disposed below the resonator,
wherein the Bragg reflective layer comprises a first reflective layer having a first acoustic impedance and a second reflective layer stacked on the first reflective layer and having a second acoustic impedance, which is lower than the first acoustic impedance.

14. The bulk-acoustic wave resonator package of claim 2, wherein a groove-shaped cavity is disposed on an upper surface of the support substrate,
wherein the resonator is spaced apart from the support substrate by the cavity.

15. The bulk-acoustic wave resonator package of claim 2, further comprising a connection substrate disposed between the support substrate and the package substrate and mounted on the package substrate,
wherein the bonding portion is interposed between the support substrate and the connection substrate.

16. A bulk-acoustic wave resonator package, comprising:
a package substrate;
a support substrate bonded to the package substrate;
a resonator disposed on the support substrate, and comprising a sequentially stacked first electrode, piezoelectric layer, and second electrode;
a bonding wire electrically connecting the resonator to the package substrate; and
a cover bonded to the package substrate and defining an accommodation space for accommodating the resonator, the support substrate, and the bonding wire,
wherein a hydrophobic layer is disposed on a surface of the resonator.
